(19) United States
(12) Patent Application Publication
(10) Pub. No.: US 2001/0056331 A1
(43) Pub. Date: Dec. 27, 2001

(54) Procedure and device for determining the signal-to noise ratio of a signal

(75) Inventors: Kang Lu, Stuttgart (DE); Rolf Matzner, Munchen (DE); Witthaya Panyaworayan, Neubiberg (DE)

Correspondence Address: SUGHRUE, MION, ZINN, MACPEAK & SEAS, PLLC, 2100 Pennsylvania Avenue, N.W., Washington, DC, 20037-3212, US

(73) Assignee: ALCATEL

(21) Appl. No.: 09/852,653

(22) Filed: May 11, 2001

(30) Foreign Application Priority Data
May 17, 2000 (DE) 100 24 326:6

(51) Int. Cl. G01R 29/26; H04B 17/00

(52) U.S. Cl. 702/69; 455/67.3; 455/226.3

(57) ABSTRACT

The invention concerns a procedure for determining the signal-to-noise ratio (ρ) of a signal (y) with wanted signal components (x) and noise signal components (n), it being assumed that the noise signal components (n) have a Gaussian distribution. In order that the signal-to-noise ratio of the signal (y) can be calculated in an accurate and reliable manner, including, in particular, when there are only relatively few measurement values (S) per measurement interval or when there is only a relatively poor signal (y) with a high noise signal component (n), it is proposed that the signal (y) be manipulated, before the signal-to-noise ratio (ρ) is determined, in such a way that the noise signal components (n) have a greater probability of having a Gaussian distribution. It is proposed, according to a development, that a noise signal (n′) with a known power be added to the signal (y). The noise signal (n′) preferably has a Gaussian distribution.

### DESCRIPTION

The present invention concerns a procedure (method) and a device for determining the signal-to-noise ratio of a signal with wanted signal components and noise signal components, it being assumed that the noise signal components have a Gaussian distribution. The invention also concerns a control element for such a device. Finally, the invention also concerns a receiver of a communications transmission path with a device for determining the signal-to-noise ratio of a received signal with wanted signal components and noise signal components, it being assumed that the noise signal components have a Gaussian distribution.

In the specialist literature, the signal-to-noise ratio (SNR) is also referred to as signal-to-interference ratio (SIR). In the domain of radio telecommunications, for example, the signal-to-noise ratio is a criterion of the transmission quality of mobile telephones and base stations.

A whole range of procedures (method) and devices for determining the signal-to-noise ratio are known from the prior art. Thus, for example, there is known from the publication by Matzner, R., Letsch, K., “SNR Estimation and Blind Equalization (Deconvolution) Using the Kurtosis”, Proc. 1994 IEEE-IMS Workshop on Information Theory and Statistics, Alexandria, Va., October. 1994, p. 68, http://speedy.et.unibw-muenchen.de/forsch/ut/publ/itstat94/paper.html [1], a procedure for determining the signal-to-noise ratio by means of the kurtosis. Express reference is made to this publication. The kurtosis is the quotient from the fourth moment of the signal of which the signal-to-noise ratio is to be determined and the square of the second moment of the signal. The kurtosis is not dependent on the signal power.

These known procedures (method) and devices operate with time-discrete signals. A determinate number of measurement values (samples) of the signal is recorded in predefined measurement intervals and the signal-to-noise ratio for these measurement values is determined by evaluating the measurement values by means of particular equations. Common to all of these known procedures and devices is the fact that, in the determination of the signal-to-noise ratio, for the purpose of simplifying the equations they proceed from the assumption that the noise signal component of the signal has a Gaussian distribution.

This assumption is only valid, however, if a sufficiently large number of measurement values is recorded per measurement interval. If the number of measurement values is too small, outliers have a substantially greater effect on the measurement result and cause the measurement result to deviate from the actual measurement value by a relatively large amount. In the case of the procedure described in [1], a sufficient number of measurement values is given as from approximately 20 to 30 measurement values per measurement interval. Moreover, the assumption made is only valid to a limited extent for a poor signal in which the signal-to-noise ratio is relatively small. In the case of a poor signal, the probability of outliers is relatively large, so that relatively large deviations of the measurement result can also occur in such a case. Overall, it can be stated that, in the case of the known procedures, a statistical measurement method is used which works more reliably and accurately the more measurement values it has available per measurement interval.

If the assumption that the noise signal components of the signal have a Gaussian distribution is not fulfilled in practice, the signal-to-noise ratio ascertained by the known procedure can have negative or even complex values. Such values, however, cannot be used further for improving the signal-to-noise ratio, e.g., for increasing the transmission power of the wanted signal components or for compensating the noise signal components of the signal.

The use of the kurtosis in communications technology is also known from U.S. Pat. No. 4,530,076. In that case, the kurtosis is used for improving the signal-to-noise ratio of a signal by eliminating from the signal noise signal components which do not have a Gaussian distribution.

The object of the present invention is to calculate in an accurate and reliable manner the signal-to-nose ratio of a signal with wanted signal components and noise signal components, including, in particular, when there are only relatively few measurement values per measurement interval or when there is only a relatively poor signal with a high noise signal component.

To achieve this object, the invention, taking as a basis the procedure of the initially mentioned type, proposes that the signal be manipulated, before the signal-to noise ratio is determined, in such a way that the noise signal components have a greater probability of having a Gaussian distribution.

The procedure according to the invention creates the condition whereby the assumption made in determining the signal-to-noise ratio according to the known procedures is normally fulfilled. In any case, the assumption is fulfilled substantially more frequently than in the case of the procedures known from the prior art. With the procedure according to the invention, therefore, the signal-to-noise ratio of a signal with wanted signal components and noise signal components can be calculated with substantially greater accuracy and reliability. This applies, in particular, if there are only relatively few measurement values per measurement interval or if there is only a relatively poor signal with a high noise signal component.

According to an advantageous development of the present invention, it is proposed that the signal is manipulated in at least one pass until the ascertained signal-to-noise ratio has no imaginary component and is positive. If, after the first pass, the ascertained signal-to-noise ratio is still negative or has an imaginary component, i.e., if the value is not plausible, the signal is manipulated again in a further pass. This loop is executed until the value of the ascertained signal-to-noise ratio is plausible or, alternatively, until a defined number of passes has been executed. In this way it can be assured that a plausible value for the signal-to-noise ratio is generally output at the end of the procedure. Such a plausible value can then be used further for improving the signal-to-noise ratio, for example, for increasing the transmission power of the wanted signal components or for compensating the noise signal components of the signal.

According to a preferred embodiment of the present invention, it is proposed that a noise signal with a known average power be added to the signal before the signal-to-noise ratio is determined. The addition of the noise signal substantially increases the probability that the noise signal components of the sum signal—i.e., the sum of the original signal and the noise signal—will have a Gaussian distribution. The positive effect of this is particularly evident in the case of a low number of measurement values per measurement interval and in the case of poor signals. This embodiment of the invention renders possible, by simple means, a substantially more accurate and more reliable determination of the signal-to-noise ratio. The average power is related to several noise values of the noise signal which are added to the measurement values of the signal within a measurement interval.

The noise signal which is added to the signal preferably has a Gaussian distribution. Stated more precisely, the noise values which are added to the individual measurement values of the signal of a measurement interval have a Gaussian distribution. The noise signal, or the individual noise values, can be taken, for example, from a memory, by means of a random generator if necessary.

According to a further preferred embodiment of the present invention, it is proposed that the signal-to-noise ratio be estimated using the kurtosis, the kurtosis being the quotient from the fourth moment of the signal and the square of the second moment of the signal. Such a procedure for estimating the signal-to-noise ratio is known from the publication [1], to which express reference is made. Supplementing this procedure by the manipulation of the signal, according to the invention, with the aim that the noise signal components of the signal have a Gaussian distribution, results in a procedure for determining the signal-to-noise ratio of a signal which is particularly simple to perform but is nevertheless accurate and reliable.

The effects of the noise signal on the signal are preferably compensated following the determination of the signal-to-noise ratio. The effects of the noise signal on the signal are preferably compensated, following the determination of the signal-to-noise ratio, according to the following equation

$$ρ = \frac{( 1 + a ) \cdot {ρ}^{′}}{a - {ρ}^{′}} \qquad 1$$

wherein ρ′ is the signal-to-noise ratio of the sum signal from the sum of the signal and the noise signal and a is the power ratio of the signal to the noise signal.

In the case of several passes, it is proposed that the power ratio a be determined from the average estimated signal-to-noise ratio of a previous measurement interval. The power ratio a is typically equal to a factor<1 multiplied by the signal-to-noise ratio of the previous measurement interval.

According to another, further advantageous embodiment of the present invention, it is proposed that the procedure for determining the signal-to-noise ratio of a Universal Mobile Telecommunication System (UMTS) signal be used. In UMTS, the determination or estimation of the signal-to-noise ratio plays a very decisive role. Most of the fundamental functions in UMTS, such as power control, handover, etc. are based on an effectively functioning ascertainment of the signal-to-noise ratio. In the case of UMTS, for many major services, such as the telephone service, there are generally only relatively few measurement values available per measurement interval for determining the signal-to-noise ratio. Thus, in the case of UMTS, for example, only a very short time interval, with correspondingly few measurement values, is provided for power control within a time slot. The advantages of the procedure according to the invention apply particularly to a so-called downlink connection from a base station to a terminal device, since in this case the power of the noise signal component can fluctuate considerably from one measurement interval to another and, consequently, a blind estimation measurement method such as the procedure proposed here must be applied.

Of particular significance is the realization of the procedure according to the invention in the form of a control element which is provided for a controller of a device for determining the signal-to-noise ratio of a signal. Stored on this control element is a program which is capable of being executed on a computing device, in particular, on a microprocessor, and is suitable for execution of the procedure according to the invention. In this case, therefore, the invention is realized through a program, so that this control element provided with the program constitutes the invention in the some way as the procedure for the execution of which the program is suitable. In particular, an electrical storage medium, e.g. a read-only memory or flash memory, can be used as a control element.

As a further means of achieving the object of the present invention, it is proposed, taking as a basis the device of the initially mentioned type, that the device comprises means for manipulating the signal prior to the determination of the signal-to-noise ratio, the means for manipulation manipulating the signal in such a way that the noise signal components have a greater probability of having a Gaussian distribution.

Finally, as a further means of achieving the object of the present invention, taking as a basis the receiver of the initially mentioned type, it is proposed that the device comprises means for manipulating the signal prior to the determination of the signal-to-noise ratio, the means for manipulation manipulating the signal in such a way that the noise signal components have a greater probability of having a Gaussian distribution.

Further features, application possibilities and advantages of the invention are disclosed by the following description of embodiment examples of the invention, which are represented in the drawing. All described or represented features, whether individually or in combination, constitute the subject-matter of the invention, irrespective of their combination in the claims or their reference association, and irrespective of their wording or representation in the description or in the drawing respectively, wherein:

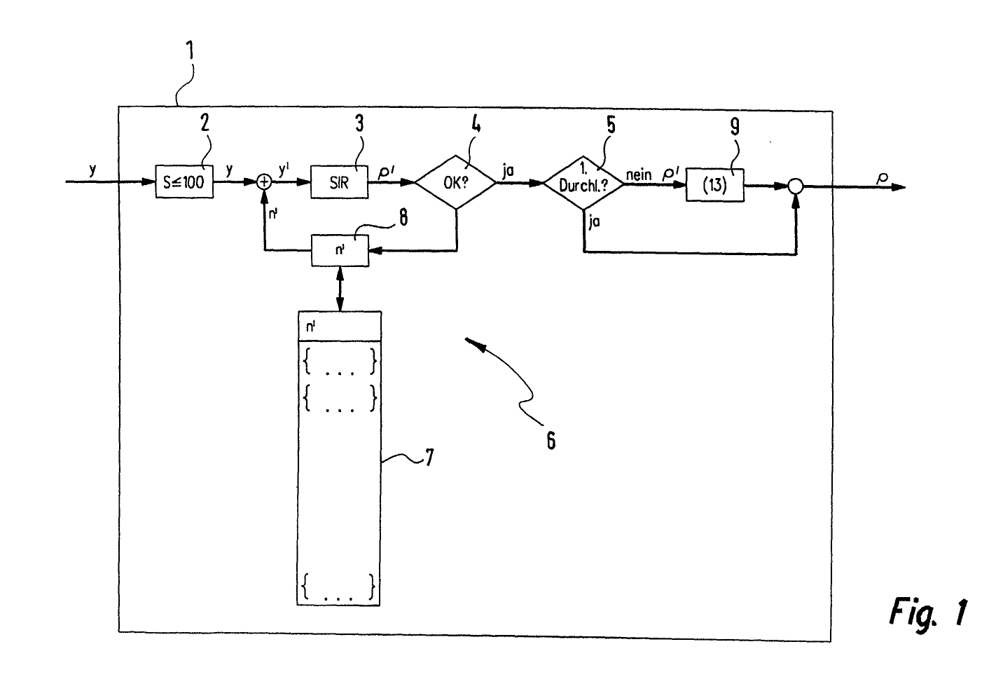

FIG. 1 shows a schematic view of a preferred embodiment of a device according to the invention; and

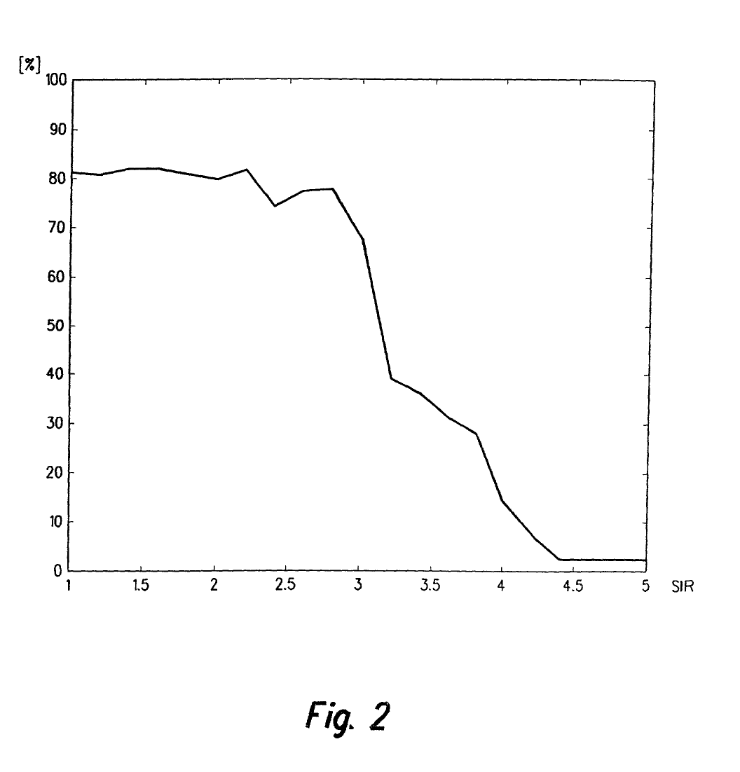

FIG. 2 shows a diagram demonstrating the capability of the procedure according to the invention.

In FIG. 1, reference 1 denotes a device according to the invention for determining the signal-to-noise ratio ρ of a signal y. The signal-to-noise ratio ρ is a criterion of the transmission quality in, for example, mobile telephones. The signal y has the form of, for example, a UMTS signal. In UMTS, the determination or estimation of the signal-to-noise ratio ρ plays a very decisive role, since most of the fundamental functions in UMTS, such as power control, handover, etc. are based on an effectively functioning, i.e., accurate and reliable, ascertainment of the signal-to-noise ratio ρ. The signal y comprises wanted signal components x and noise signal components n. The signal y exists as a time-discrete signal, there being a determinate number of measurement values (samples) S available within a predefinable measurement interval. At the input to the device 1, the number of measurement values S per measurement interval is limited in a function block 2 to a maximum of 100. By this means, the computation effort for determining the signal-to-noise ratio ρ can be kept within reasonable limits.

In a function block 3 the signal-to-noise ratio ρ is estimated according to a procedure known from the prior art. Such a known procedure is described in, for example, the publications by Matzner, R., Letsch, K., “SNR Estimation and Blind Equalization (Deconvolution) Using the Kurtosis”, Proc. 1994 IEEE-IMS Workshop on Information Theory and Statistics, Alexandria, Va., October. 1994, p. 68, http://speedy.et.unibw-muenchen.de/forsch/ut/publ/itstat94/ paper.html [1].

Stated below, in the frequency domain, are the relevant complex equations for the procedure according to the invention. It is understood that a simplification of the equations can be achieved through representation as a real equation and that the equations can also be easily represented in the time domain through an appropriate transformation.

The principle proceeded from, firstly, is that a noise signal n′=0 and therefore y′=y. The known procedure described in [1] proceeds from the assumption that the wanted signal components x and the noise signal components n of the signal y are statistically independent of one another. The probability density function (pdf) f_{y}(y) of the signal y=x+n results from the convolution of the probability density function fₓ(y) of the wanted signal component x and probability density function fₙ(y) of the noise signal component n in the time domain.

The Fourier transform of a probability density function is designated as a characteristic function CF. A convolution in the time domain corresponds to a simple multiplication in the frequency domain:

ø_{y}(ω₁,ω₂)=øₓ(ω₁,ω₂)øₙ(ω₁,ω₂) 2

The characteristic function Φ_{y}(ω₁, ω₂) can be expanded in a Taylor series. The coefficients of the Taylor series are the moments of the probability density function:

$${φ}_{y} ( {ω}_{1} , {ω}_{2} ) {\sum }_{p = 0}^{∞} \frac{{( - j )}^{p}}{p !} {\sum }_{q = 0}^{∞} ( \begin{matrix}p \\ q\end{matrix} ) {m}_{y , p - q , q} {ω}_{1}^{p - q} {ω}_{2}^{q} \qquad 3$$

By reason of this relationship, the Taylor expansion of a characteristic function is also referred to as a moment series. For symmetrical probability density distributions, the characteristic function is a real function and all uneven order moments disappear. The use of the moment series to represent the characteristic functions in equation (3) results in the following expression:

$${m}_{y , k , i} = {\sum }_{u = 0}^{k} {\sum }_{v = 0}^{i} ( \begin{matrix}k \\ u\end{matrix} ) ( \begin{matrix}l \\ v\end{matrix} ) {m}_{x , k - u , l - v} {m}_{n , u , v} \qquad 4$$

It is sufficient to work with the second and fourth order moments. The second order moments m_{y,2} and fourth order moments m_{y,4} give:

m_{y,2}=m_{x,2,0}+m_{x,0,2}+m_{n,2,0}+m_{n,0,2}

m_{y,4}=m_{x,4,0}+2m_{x,2,2}+m_{x,0,4}+m_{n,4,0}+2m_{n,2,2}+m_{n,0,4}++4(m_{x,2,0}+m_{x,0,2})(m_{x,2,0}+m_{n,0,2})++2(m_{x,2,0}−m_{x,0,2})(m_{n,2,0}−m_{n,0,2}) 5

It is appropriate at this point to introduce the so-called kurtosis K_{y} of the signal y. The most important attribute of the kurtosis K_{y} is that it is non-dependent on the power of the signal y. This means that the kurtosis K_{y} is a form factor of a probability density function.

$${K}_{y} = \frac{{m}_{y , 4}}{{( {m}_{y , 2} )}^{2}} = \frac{{K}_{x} {S}^{2} + {K}_{n} {N}^{2} + 4 SN + 2 ( {S}_{r} - {S}_{i} ) ( {N}_{r} - {N}_{i} )}{{( S + N )}^{2}} \\ mit S = {S}_{r} + {S}_{i} = {m}_{x , 2 , 0} + {m}_{x , 0 , 2} und \\ N = {N}_{r} + {N}_{i} = {m}_{n , 2 , 0} \qquad 6$$

The fourth order moments of the wanted signal component x and of the noise signal component n have been replaced by the corresponding kurtosis Kₓ and Kₙ. Following appropriate transformation, an equation is obtained which contains only second order moments and kurtoses:

$${K}_{y} = \frac{{K}_{x} {S}^{2} + {K}_{n} {N}^{2} + 4 SN}{{( S + N )}^{2}} \qquad 7$$

This already almost represents the solution of the estimation problem: Kₓ and Kₙ are form factors of the probability density functions of the wanted signal component x and of the noise signal component n, which are known. K_{y} can be obtained through observation of the signal y. It is thus sufficient to solve the equation (7) for S/N, which is the estimated signal-to-noise ratio.

The expression which is of interest in equation (7) is the mixed expression 4SN. The equation (7) can be formulated considerably better with a quantity G with, in the complex case, G=K−2.

G is 0 for a Gaussian distribution and negative for the majority of typical modulated and baseband sources. By replacing the kurtoses K of the wanted signal component x and of the signal y by the respective quantity G in equation (7), and assuming that Gₙ=0 (valid for a noise signal n with a Gaussian distribution), a very clear equation is obtained:

$$\begin{matrix}{G}_{y} = {{G}_{x} ( \frac{S}{S + N} )}^{2} = {{G}_{x} ( \frac{{m}_{x , 2 , 0} + {m}_{x , 0 , 2}}{{m}_{x , 2 , 0} + {m}_{x , 0 , 2} + {m}_{n , 2 , 0} + {m}_{n , 0 , 2}} )}^{2} & 8 \\ \text{With} κ = \frac{S}{S + N} = \frac{{m}_{x , 2}}{{m}_{x , 2} + {m}_{n , 2}} & 9\end{matrix}$$

With

there is obtained from equation (8) a simple expression for the signal-t-noise ratio.

$${G}_{y} = {G}_{x} {κ}^{2} , ρ = \frac{κ}{1 - κ} \qquad 10$$

As observable from equation (10), the known procedure for determining the signal-to-noise ratio ρ proceeds from the assumption that the noise signal component n of the signal y has a Gaussian distribution.

This assumption is only valid, however, if a sufficiently large number of measurement values S is recorded per measurement interval. If the number of measurement values S is too small, outliers have a substantially greater effect on the measurement result and cause the measurement result to deviate from the actual measurement value by a relatively large amount. In the case of the procedure described above, a sufficient number of measurement values is given as from approximately 20 to 30 measurement values per measurement interval. Moreover, the assumption made is only valid to a limited extent for a poor signal y in which the signal-to-noise ratio ρ is relatively small. In the case of a poor signal y, the probability of outliers is relatively large, so that relatively large deviations of the measurement result can also occur in such a case. In summary, in the case of the known procedures, a statistical measurement method is used which works more reliably and accurately the more measurement values S are available per measurement interval.

In the case of UMTS, there are generally only relatively few measurement values S available per measurement interval for determining the signal-to-noise ratio ρ. Thus, in the case of UMTS according to the current state of the art, only a very short time interval, with correspondingly few measurement values S, is provided for power control within a time slot. In the case of a downlink connection from a base station to a terminal device there is also added the following limitation, so that effectively only blind estimation procedures can be used for ascertaining the signal-to-noise ratio. The terminal device, as a receiver in the downlink connection, expects power fluctuations in both the wanted signal component and the noise signal component. For this reason the noise signal component cannot be measured separately from the wanted signal component, as in the case of an uplink connection. Moreover, the number of pilot bits known in advance is not sufficient for this estimation task.

A sampling block 4 following the function block 3 checks whether the signal-to-noise ratio ρ calculated in function block 3 by means of the known procedure is plausible. It is plausible if it contains only real components and is positive. If the signal-to-noise ratio ρ is plausible, a subsequent sampling block 5 checks whether the process is still in the first pass. If that is the case, ρ=ρ′ and the signal-to-noise ratio ρ determined in function block 3 is output.

If, however, it is determined in the sampling block 4 that the signal-to-noise ratio ρ ascertained in the function block 3 is not plausible, then, according to the invention, a branching operation is performed to means 6 for manipulating the signal. The means 6 manipulate the signal y in such a way that the noise signal components n have a greater probability of having a Gaussian distribution. In this embodiment example, the means 6 are designed so that a noise signal n′ is added to the signal y. The noise signal n′ has a Gaussian distribution. The noise signal n′ consists of a plurality of individual noise values which are stored in the form of a list or table in a storage element 7. The noise values are, for example, front-end generated by means of a random generator (not depicted) and stored in the storage element 7. An appropriate noise value is added to each measurement value S within a measurement interval. The appropriate noise value is selected by means of a selector element 8. In the simplest case, one noise value after another is read out from the list in the storage element 7. It is also conceivable, however, for a noise value to be randomly selected from the list.

The signal-to-noise ratio ρ′ of the sum signals y′=y+n′ is then calculated in the function block 3.

$$\begin{matrix}{ρ}^{′} = \frac{{m}_{x , 2}}{{m}_{n , 2} + {m}_{{m}^{′} , 2}} \\ = \frac{a ρ}{a + 1 + ρ}\end{matrix} \qquad 11$$

The variable a is the power ratio of the signal y to the noise signal n′. The power ratio a can be adaptively determined from the estimated value of the signal-to noise ratio ρ from a previous measurement inter/al. The power ratio a is typically equal to a factor f<1 multiplied by the signal-to-noise margin of the previous measurement interval. A typical value for the factor f is f≈0.25.

The sampling block 4 then checks whether the signal-to-noise ratio ρ′ ascertained in function block 3 is plausible. If it is plausible, the subsequent sampling block 5 checks whether the process is still in the first pass. Since the process is already in its second pass, a branching operation is performed to a function block 9 in which the signal-to-noise ratio ρ′ of the sum signals y′ is converted to the actual signal-to-noise ratio ρ of the signal y. The following relationship applies:

$$ρ = \frac{( 1 + a ) {ρ}^{′}}{a - {ρ}^{′}} \qquad 1$$

The ascertained value for the signal-to-noise ratio ρ is then output and the procedure according to the invention is complete.

If it is determined in the sampling block 4 that the ascertained signal-to-noise ratio ρ′ is not plausible, another branching operation is performed to the means 6 for manipulating the signal y and a noise signal n′ is added to the signal y. The noise signal n′ selected for the further pass generally differs from the noise signal n′ of the preceding passes. This loop is executed until there is a plausible value for the signal-to-noise ratio ρ′. If a predefinable number of passes has been executed without being able to ascertain a plausible value, the procedure is aborted.

The aim of the procedure according to the invention is to achieve a Gaussian distribution of the sum signal y′. For this purpose, it is not necessary that the noise signal n′ has a Gaussian distribution, although it is advantageous if the noise signal n′ does have a Gaussian distribution. The average power of the noise signal n′ is known. It is either 0 or is compensated following the ascertainment of the signal-to-noise ratio ρ.

The procedure according to the invention has been described for the time-discrete signals y(k), k=0, 1, 2, 3, . . . It is also applicable, however, to time-continuous signals y(t).

FIG. 2 shows a diagram demonstrating the capability of the procedure according to the invention. The diagram contains all the signal-to-noise ratios ρ which were implausible (with imaginary component and/or negative) after the first pass (corresponds to 100%). The abscissa indicates the signal-to noise ratio ρ. The ordinate indicates the percentage number of ascertained signal-to-noise ratios ρ for which a plausible value was obtained by manipulation of the signal y by means of the procedure according to the invention. The diagram shown in FIG. 2 is based on a signal y for which 20 measurement values S per measurement interval were available. The maximum number of passes was limited to 30.

It is clearly evident from FIG. 2 that the procedure according to the invention results in a substantial increase in the number of plausible values for the signal to noise ratio ρ, particularly in the case of poor signals y, i.e., in the case of small signal-to-noise ratios ρ, in particular, in the case of ρ<3. Since only the plausible values can be processed further, a data transmission can be optimized in a substantially improved manner by means of the procedure according to the invention.

1. Method for determining the signal-to-noise ratio (ρ) of a signal (y) with wanted signal components (x) and noise signal components (n), it being assumed that the noise signal components (n) have a Gaussian distribution, characterized in that the signal (y) is manipulated, before the signal-to-noise ratio (ρ) is determined, in such a way that the noise signal components (n) have a greater probability of having a Gaussian distribution.

2. Method according to claim 1, characterized in that the signal is manipulated in at least one pass until the ascertained signal-to-noise ratio (ρ) has no imaginary component and is positive.

3. Method according to either of claims 1 or 2, characterized in that a noise signal (n′) with a known power is added to the signal (y) before the signal-to-noise ratio (ρ) is determined.

4. Method according to claim 3, characterized in that the noise signal (n′) has a Gaussian distribution.

5. Method according to any one of claims 1 to 4, characterized in that the signal-to-noise ratio (ρ) is estimated using the kurtosis (K_{y}), the kurtosis (K_{y}) being the quotient from the fourth moment (m_{y,4}) of the signal (y) and the square of the second moments (m_{y,2}) of the signal (y).

6. Method according to any one of claims 3 to 5, characterized in that the effects of the noise signal (n′) on the signal (y) are compensated following the determination of the signal-to-noise ratio (ρ).

7. Method according to claim 6, characterized in that the effects of the noise signal (n′) on the signal (y) are compensated, following the determination of the signal-to-noise ratio (ρ), according to the following equation
$$ρ = \frac{( 1 + a ) \cdot {ρ}^{′}}{a - {ρ}^{′}} \qquad 1$$
wherein ρ′ is the signal-to-noise ratio of the sum signal (y′) from the sum of the signal (y) and the noise signal (n′) and a is the power ratio of the signal (y) to the noise signal (n′).

8. Method according to claim 7, characterized in that a is determined from the average estimated signal-to-noise ratio (ρ) of a previous pass of the procedure.

9. Method according to any one of claims 1 to 8, characterized in that the procedure for determining the signal-to-noise ratio (ρ) of a Universal Mobile Telecommunication System (UMTS) signal (y) is used.

10. Control element, in particular, a read-only memory or flash memory, for a controller of a device for determining the signal-to-noise ratio (ρ) of a signal (y), on which there is stored a program which is capable of being executed on a computing device, in particular, on a microprocessor, and is suitable for the execution of a method according to any one of the preceding claims.

11. Device for determining the signal-to-noise ratio (ρ) of a signal (y) with wanted signal components (x) and noise signal components (n), it being assumed that the noise signal components (n) have a Gaussian distribution, characterized in that the device comprises means for manipulating the signal (y) prior to the determination of the signal to-noise ratio (ρ), the means for manipulation manipulating the signal (y) in such a way that the noise signal components (n) have a greater probability of having a Gaussian distribution.

12. Receiver of a communications transmission path with a device for determining the signal-to-noise ratio (ρ) of a received signal (y) with wanted signal components (x) and noise signal components (n), it being assumed that the noise signal components (n) have a Gaussian distribution, characterized in that the device comprises means for manipulating the signal (y) prior to the determination of the signal-to-noise ratio (ρ), the means for manipulation manipulating the signal (y) in such a way that the noise signal components (n) have a greater probability of having a Gaussian distribution.
